(19) United States
(12) Patent Application Publication
(10) Pub. No.: US 2016/0244892 A1
(43) Pub. Date: Aug. 25, 2016

(54) Method for Crystallizing Group IV Semiconductor, and Film Forming Apparatus

(71) Applicant: TOKYO ELECTRON LIMITED, Tokyo (JP)

(72) Inventors: Kazuya TAKAHASHI, Nirasaki City (JP); Mitsuhiro OKADA, Nirasaki City (JP); Katsuhiko KOMORI, Nirasaki City (JP); Hiromasa YONEKURA, Nirasaki City (JP)

(21) Appl. No.: 15/042,875

(22) Filed: Feb. 12, 2016

(30) Foreign Application Priority Data
Feb. 19, 2015 (JP) 2015-030323

(51) Int. Cl. C30B 29/06; H01L 21/67; C30B 29/08; C30B 9/10; C30B 33/08; H01L 21/02; C30B 19/02

(52) U.S. Cl. CPC C30B 29/06; H01L 21/02532; H01L 21/0262; H01L 21/02592; H01L 21/02669; H01L 21/67109; H01L 21/67115; H01L 21/67069; C30B 19/02; C30B 9/10; C30B 33/08; C30B 29/08

(57) ABSTRACT

A method for crystallizing a group IV semiconductor to form group IV semiconductor crystals on a process surface of a workpiece on which a process is performed, includes forming an additive-containing group IV semiconductor film on the process surface of the workpiece by supplying a group IV semiconductor precursor gas serving as a precursor of the group IV semiconductor and an additive gas which lowers a melting point of the group IV semiconductor and which includes an additive whose segregation coefficient is smaller than “1”, liquefying the additive-containing group IV semiconductor film, and solidifying the liquefied additive-containing group IV semiconductor film from the side of the process surface of the workpiece to form the group IV semiconductor crystals.

### CROSS-REFERENCE TO RELATED APPLICATION

This application claims the benefit of Japanese Patent Application No.2015-030323, filed on Feb. 19, 2015, in the Japan Patent Office, the disclosure of which is incorporated herein in its entirety by reference.

### TECHNICAL FIELD

The present disclosure relates to a method for crystallizing a group IV semiconductor, and a film forming apparatus.

### BACKGROUND

In manufacturing a semiconductor device using a group IV semiconductor formed by deposition, such as silicon or the like, as a channel, a process such as laser annealing or SPC (Solid Phase Crystallization) is carried out in order to magnify grains of the deposited silicon.

However, when the amorphous silicon is crystallized by the laser annealing or SPC, the amorphous silicon eventually becomes poly-crystalline structure since the crystallization progresses from the inside of the amorphous silicon. When the poly-crystallized silicon is used as a channel, a value of current flowing through the channel is determined depending on the grain size.

In addition, since the gains are randomly grown in the amorphous silicon, the deviation in variations of the value of a current flowing through the channel may increase.

### SUMMARY

Some embodiments of the present disclosure provide a method for crystallizing a group IV semiconductor, which is capable of suppressing poly-crystallization of a group IV semiconductor and obtaining group IV semiconductor crystals closer to single crystals, and a film forming apparatus which is capable of performing the method for crystallizing a group IV semiconductor.

According to the first embodiment of the present disclosure, there is provided a method for crystallizing a group IV semiconductor to form group IV semiconductor crystals on a process surface of a workpiece on which a process is performed, the method including forming an additive-containing group IV semiconductor film on the process surface of the workpiece by supplying a group IV semiconductor precursor gas serving as a precursor of the group IV semiconductor and an additive gas which lowers a melting point of the group IV semiconductor and which includes an additive whose segregation coefficient is smaller than “1”, liquefying the additive-containing group IV semiconductor film, and solidifying the liquefied additive-containing group IV semiconductor film from the side of the process surface of the workpiece to form the group IV semiconductor crystals.

According to the second embodiment of the present disclosure, there is provided a film forming apparatus for forming a film of a group IV semiconductor on a process surface a workpiece on which a process is performed, the apparatus including a processing chamber in which the workpiece is subjected to a predetermined process, a gas supply mechanism including a group IV semiconductor precursor gas supply source for supplying a group IV semiconductor precursor gas serving as a precursor of the group IV semiconductor into the processing chamber and an additive gas supply source for supplying an additive gas which lowers a melting point of the group IV semiconductor and which includes an additive whose segregation coefficient is smaller than “1”, a heating device for heating an interior of the processing chamber, and a controller for controlling the gas supply mechanism and the heating device, wherein the controller controls the gas supply mechanism and the heating device to perform the group IV semiconductor crystallizing method described above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flow chart showing one example sequence of a group IV semiconductor crystallizing method according to a first embodiment of the present disclosure.

FIGS. 2A to 2F are schematic sectional views showing a state of a workpiece in the sequence shown in FIG. 1.

FIGS. 3A to 3E are schematic sectional views showing a state of a workpiece according to a modification.

FIG. 4 is a schematic sectional view showing one example of a film forming apparatus according to a second embodiment of the present disclosure.

### DETAILED DESCRIPTION

Hereinafter, a first embodiment of the present disclosure will be described with reference to the drawings. Throughout the drawings, the same or similar elements and portions are denoted by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

<Group IV Semiconductor Crystallizing Method>

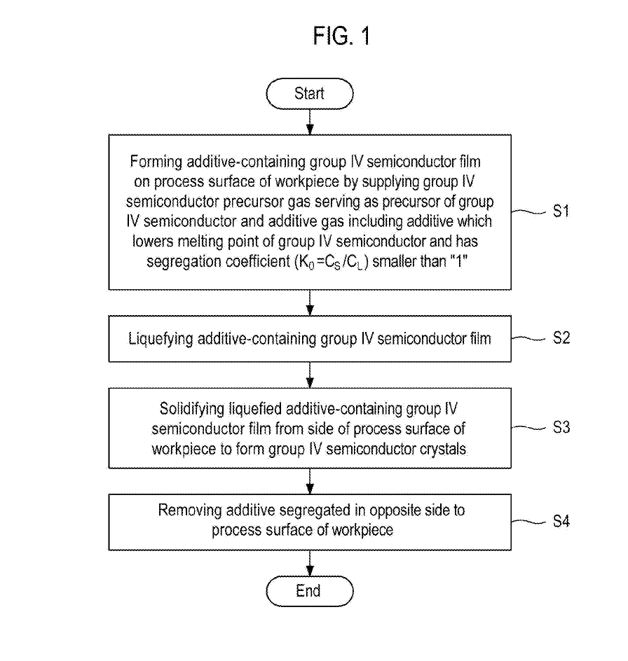

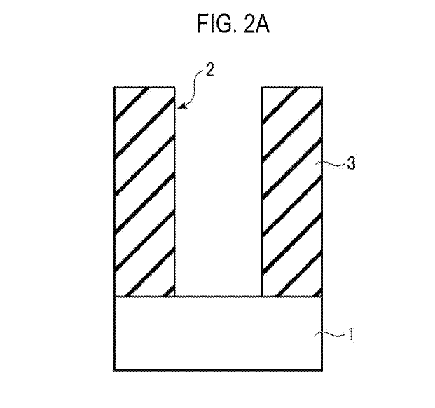

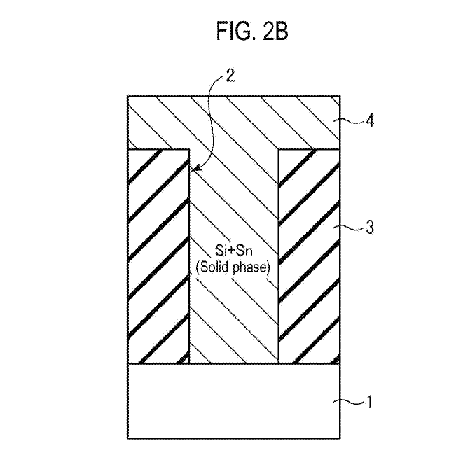

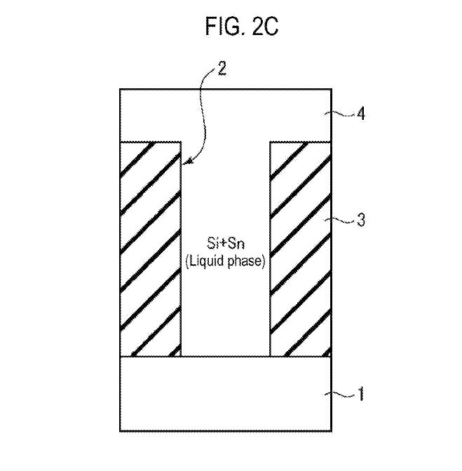

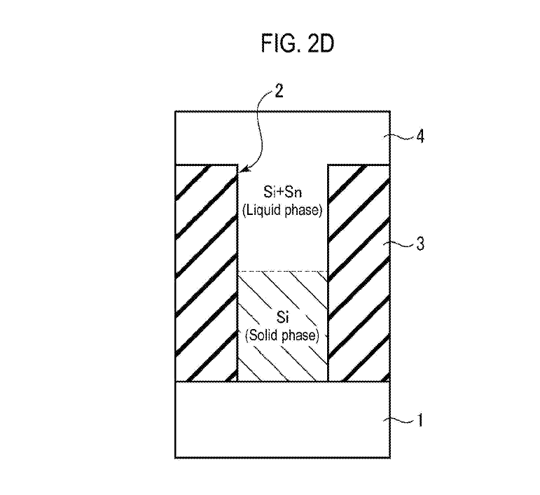

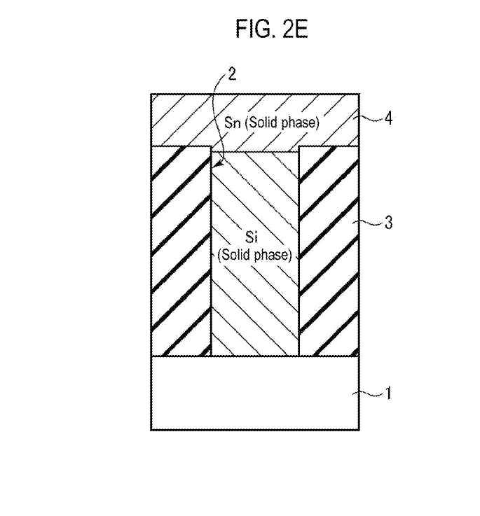

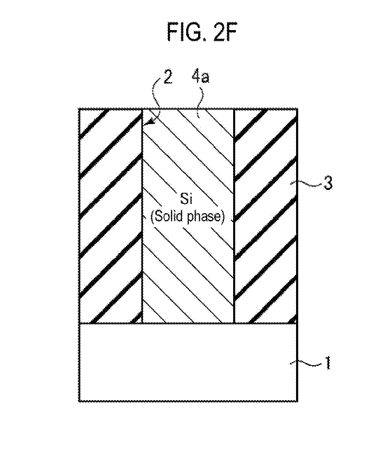

FIG. 1 is a flowchart showing one example sequence of a group IV semiconductor crystallizing method according to a first embodiment of the present disclosure. FIGS. 2A to 2F are schematic sectional views showing states of a workpiece in the sequence shown in FIG. 1.

First, a workpiece on which a group IV semiconductor film is to be formed is prepared. One example of the workpiece is a group IV semiconductor wafer 1 as shown in FIG. 2A, such as a silicon wafer (hereinafter, simply referred to as a wafer). The wafer 1 is a single-crystallized silicon wafer. Silicon single crystals exist on a process surface of the wafer 1 on which the process is performed.

The wafer 1 of this example is, for example, in the course of manufacture of a semiconductor integrated circuit device. A film having an opening 2 through which the process surface of the wafer 1 is exposed is formed on the process surface of the wafer 1. This film 3 is made of a material such as silicon oxide. The silicon oxide film 3 is amorphous and is exposed at the side wall of the opening 2.

Next, the wafer 1 having the structure shown in FIG. 2A is accommodated in a process chamber of a film forming apparatus. Subsequently, as shown in Step 51 of FIG. 1 and in FIG. 2B, an additive-containing group IV semiconductor film is formed on the process surface of the wafer 1 by supplying a precursor gas serving as a precursor of the group IV semiconductor and an additive gas containing an additive into the process chamber. In this example, a solid phase additive-containing silicon film 4 is formed on the process surface of the wafer 1 by supplying a silicon precursor gas containing silicon identical to the wafer and serving as a precursor of silicon, and an additive gas containing an additive into the process chamber. The solid phase additive-containing silicon film 4 is, for example, in an amorphous state.

In the first embodiment, a material which can lower the melting point of the group IV semiconductor (silicon in this example) and has a segregation coefficient (equilibrium distribution coefficient) K₀(=C_{S}/C_{L}) in silicon smaller than “1” is selected as an additive. One example of such an additive may include metal such as tin (Sn) when the group IV semiconductor is silicon or germanium. When the segregation coefficient Kₒ of the additive in silicon is smaller than “1,” the additive is pushed out to a liquid phase, thereby increasing the purity of the solid phase of silicon. Addition, when Sn is contained in silicon whose melting point is about 1,400 degrees C., the melting point is decreased to a temperature at which the Sn-containing silicon can be liquefied by annealing at the temperature zone ranging from 500 degrees C. or more to 900 degrees C. or less.

One example of the silicon precursor gas may include a monosilane (SiH₄) gas and one example of the additive gas may include a tin tetrachloride (SnCl₄) gas. One example of the processing conditions for Step S1 is as follows:

SiH₄ gas flow rate: 1 to 5,000 sccm

SnCl₄ gas flow rate: 0.1 to 500 sccm

Processing time: 10 to 600 min

Processing temperature: 200 to 500 degrees C.

Processing pressure: 13.33 to 666.5 Pa (0.1 to 5 Torr) (wherein, 1 Torr is defined as 133.3 Pa.).

Under the above conditions, the additive-containing silicon film 4 having the concentration of Sn as the additive of 1 to 30% is formed (Si+Sn (solid phase)) on the process surface of the wafer 1 such that the film 4 fills the inside of the opening 2 of the silicon oxide film 3.

Next, as shown in Step S2 of FIG. 1 and in FIG. 2C, the solid phase additive-containing silicon film 4 is liquefied (Si+Sn (liquid phase)). In Step S2, for example, only the additive-containing silicon film 4 is liquefied without melting the wafer 1 or a structure formed on the wafer 1. Such liquidation of the additive-containing silicon film 4 may be achieved by annealing the wafer 1. One example of such annealing may include heating the additive-containing silicon film 4 at a temperature equal to or more than the melting point of the additive-containing silicon film and less than the melting points of the wafer 1 or the structure formed on the wafer 1. One example of the annealing atmosphere may include an inert atmosphere such as a nitrogen (N₂) atmosphere. In addition to the inert atmosphere, a hydrogen (H₂) atmosphere may be possible as the annealing atmosphere.

One example of the processing conditions for Step S2 is as follows.

N₂ or H₂ gas flow rate: 1 to 20,000 sccm

Processing time: 1 sec to 600 min

Processing temperature: 500 to 900 degrees C.

Processing pressure: 13.33 to 101,325 Pa (normal pressure) (0.1 to 760 Torr)

Next, as shown in Step S3 of FIG. 1 and in FIG. 2D, silicon crystals are formed while solidifying the liquefied additive-containing silicon film 4 from the side of the process surface of the wafer 1. Step S3 may be performed by stopping the heating or decreasing the heating temperature. When the heating is stopped or the heating temperature is decreased, the liquefied additive-containing silicon film 4 is thermally dissipated through the wafer 1 with good dissipation. Thus, as the temperature of the additive-containing silicon film 4 is decreased from the side of the wafer 1, the additive-containing silicon film 4 is solidified from the side of the wafer 1 to be grown to silicon single crystals.

When the additive-containing silicon film 4 is solidified, tin serving as the additive is difficult to be introduced into a solidified portion of the film 4 since the segregation coefficient K₀ in silicon is smaller than “1”. For this reason, the solid phase silicon is left as crystals in the solidified portion. Finally, as shown in FIG. 2E, the solid phase silicon (Si (solid phase)) is segregated in the side of the process surface of the wafer 1 and solid phase tin (Sn (solid phase)) is segregated in the opposite side of the process surface of the wafer 1.

Next, as shown in Step S4 of FIG. 1 and in FIG. 2F, the solid phase tin (Sn (solid phase)) segregated in the opposite side of the process surface of the wafer 1 is removed from the solidified additive-containing silicon film 4. The solid phase tin may be removed, for example, by wet-etching with dilute hydrofluoric acid or hydrochloric acid or by chemical mechanical polishing (CMP). Thus, a crystallized silicon film 4a almost close to single crystals is formed inside the opening 2. Step S4 may be performed as necessary.

As such, the silicon film forming process using the group IV semiconductor crystallizing method according to the first embodiment is ended.

In the above-described group IV semiconductor crystallizing method according to the first embodiment, the melting point of the group IV semiconductor is lowered, the amorphous additive-containing silicon film 4 containing an additive whose segregation coefficient is smaller than “1” is formed, the additive-containing silicon film 4 is liquefied by annealing, and the liquefied additive-containing silicon film 4 is solidified from the side of the process surface of the wafer 1. In addition, single crystals of the group IV semiconductor such as silicon exist on the process surface of the wafer 1 and the additive has the segregation coefficient smaller than “1” in the group IV semiconductor such as silicon. On this account, when the additive-containing silicon film 4 is returned from the liquid phase to the solid phase, the additive such as tin is pushed out to the liquid phase. In addition, since the liquefied additive-containing silicon film 4 is cooled from the side of the process surface of the wafer 1 through the wafer 1 with good dissipation, high-pure silicon crystals are grown upward from the side of the process surface of the wafer 1.

Therefore, by the group IV semiconductor crystallizing method according to the first embodiment, poly-crystallization of the group IV semiconductor can be suppressed, as compared with a case where crystallization of silicon is developed from the inside of an amorphous silicon film using laser annealing or SPC. Thus, it is possible to obtain the group IV semiconductor crystals such as silicon crystals closer to single crystals.

In addition, since the silicon crystals are grown from the side of the process surface of the wafer 1, even when the additive-containing silicon film 4 is formed in an inside of the opening 2 whose amorphous lateral surfaces are exposed as shown in FIGS. 2A to 2F, silicon crystals closer to single crystals can be obtained.

In addition, although it has been illustrated in the first embodiment that the crystallized silicon film 4a is formed on the process surface of the single-crystallized silicon wafer 1, the group IV semiconductor is not limited to silicon. For example, germanium (Ge) may be used as the group IV semiconductor. In this case, it may use a single-crystallized germanium wafer as a workpiece. In other words, the process surface of the workpiece may have the same group IV semiconductor single crystals as a group IV semiconductor film to be crystallized in some embodiments.

In addition, although it has been illustrated in the first embodiment that tin is used as the additive, a material other than tin may be used as the additive as long as the material can lower the melting point of the group IV semiconductor and has a segregation coefficient smaller than “1”. In addition, the additive is preferably a metal. This is because the metal can be easily segregated from the group IV semiconductor when a change from a liquid phase to a solid phase occurs.

In addition, the melting point of the group IV semiconductor may be lowered in some embodiments until the group IV semiconductor can be liquefied by annealing at the temperature zone ranging from 500 degrees C. or more to 900 degrees C. The annealing at this temperature zone is suitable for practical use since a structure formed on the workpiece is less affected by heat applied thereto.

<Modifications>

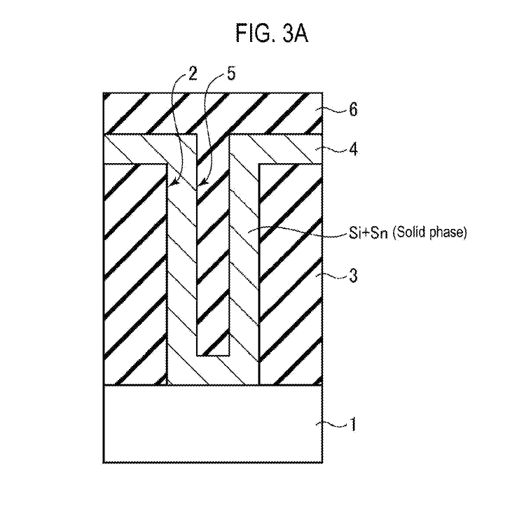

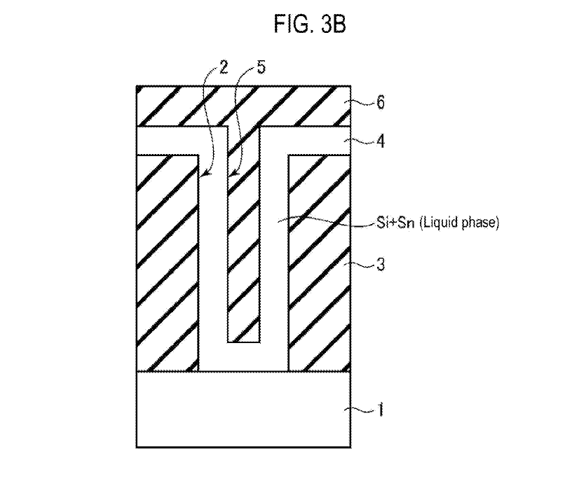

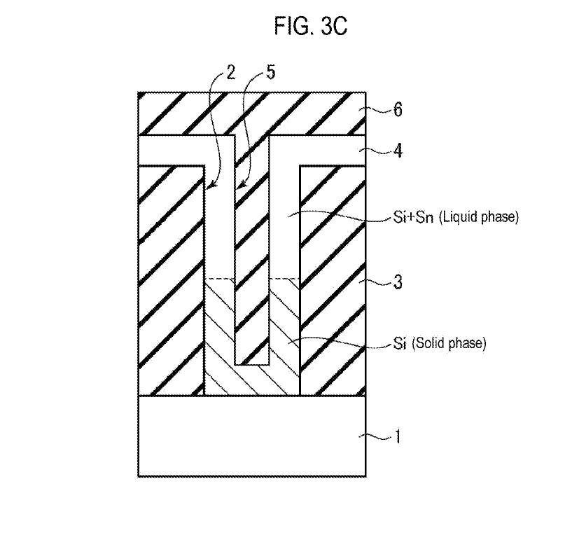

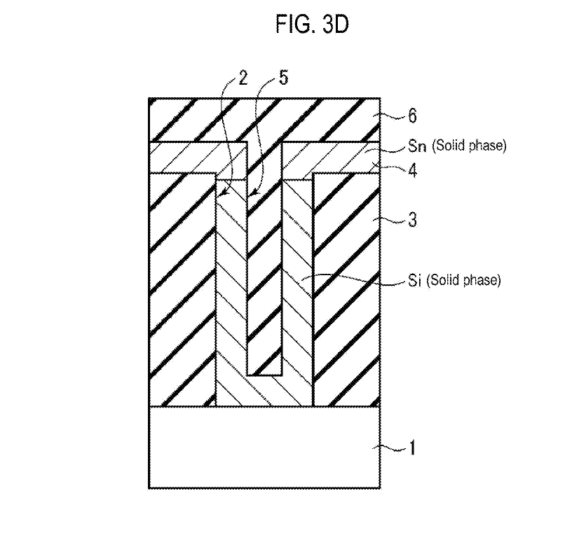

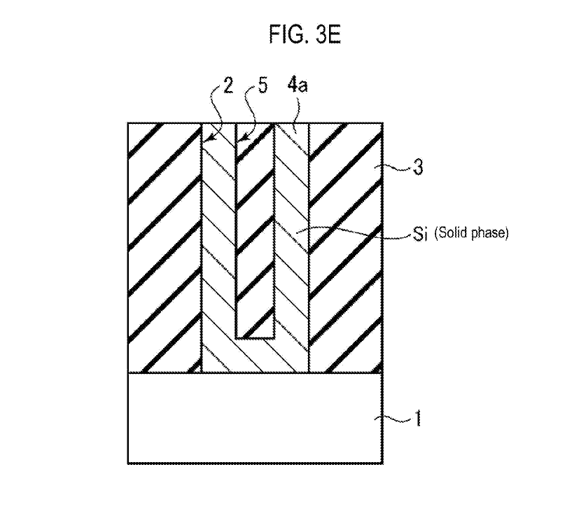

FIGS. 3A to 3E are schematic sectional views showing a state of a workpiece according to a modification.

In the group IV semiconductor crystallizing method described with reference to FIGS. 2A to 2F, the silicon film to be crystallized is formed to fill the inside of the opening 2. However, the silicon film to be crystallized is not limited to the filling of the inside of the opening 2.

For example, as shown in FIG. 3A, a structure where the additive-containing silicon film 4 (Si+Sn (solid phase)) is formed by a vapor growth, as in the first embodiment, so as to reflect the shape of the opening 2 along the lateral surface of the opening 2, and an insulating film such as a silicon oxide film 6 is formed so as to fill a concave portion 5 formed in the additive-containing silicon film 4 and to cover the additive-containing silicon film 4, may be possible.

This additive-containing silicon film 4 is liquefied (Si+Sn (liquid phase)), as shown in FIG. 3B, and is solidified (Si (solid phase)) from the side of the process surface of the wafer 1, as shown in FIG. 3C. As a result, as shown in FIG. 3D, crystallized silicon (Si (solid phase)) can be obtained in the side of the process surface of the wafer 1 and the additive-containing silicon film 4 having segregated tin (Sn (solid phase)) can be obtained in the opposite side of the process surface of the wafer 1.

In addition, as shown in FIG. 3E, as with the first embodiment, by removing a portion of the segregated tin (Sn (solid phase)) as necessary, a crystallized silicon film 4a having a structure which can be electrically isolated by the silicon oxide film 6 can be obtained in the inside of the opening 2.

In addition, the structure shown in FIG. 2F in the first embodiment can be used as an embedded conductive material of a contact hole or a via hole and the structure shown in FIG. 3E in the modification can be used as a channel of a three-dimensional transistor.

### Second Embodiment

A second embodiment involves one example of a film forming apparatus capable of performing the silicon film forming method according to the first embodiment.

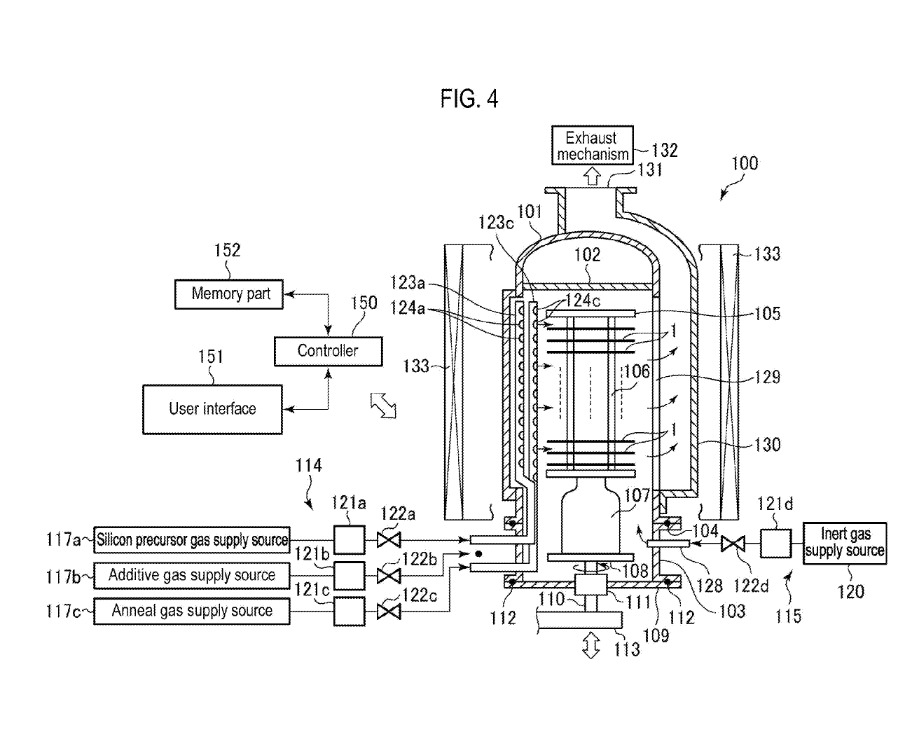

FIG. 4 is a schematic sectional view showing one example of the film forming apparatus according to the second embodiment of the present disclosure.

As shown in FIG. 4, a film forming apparatus 100 includes a cylindrical processing chamber 101 having a ceiling with a bottom end opened. The entire processing chamber 101 is made of, e.g., quartz. A quartz ceiling plate 102 is located at the inside of the ceiling of the processing chamber 101. Also, for example, a cylindrical manifold 103, which is formed of stainless steel, is connected to a lower end opening portion of the processing chamber 101 via a sealing member 104 such as an O-ring.

The manifold 103 supports a lower end portion of the processing chamber 101. A vertical wafer boat 105 made of quartz, in which a plurality of (e.g., 50 to 100) wafers 1 is vertically loaded as workpieces, can be inserted into the processing chamber 101 from a lower portion of the manifold 103. The vertical wafer boat 105 includes a plurality of supporting pillars 106, and the plurality of wafers 1 is vertically supported by grooves (not shown) formed in each of the supporting pillars 106.

The vertical wafer boat 105 is mounted on a table 108 with a quartz heat insulating tube 107 interposed between the wafer boat 105 and the table 108. The table 108 is supported on a rotation shaft 110 that passes through a cover part 109. The cover part 109 is made of, e.g., stainless steel, and opens or closes a lower end opening portion of the manifold 103. For example, a magnetic fluid seal 111 is disposed at a through portion of the rotation shaft 110. The magnetic fluid seal 111 closely seals and rotatably supports the rotation shaft 110. Also, for example, a seal member 112 such as an O-ring is interposed between the periphery of the cover part 109 and a lower end portion of the manifold 103. Thus, sealability is maintained in the processing chamber 101. The rotation shaft 110 is disposed at, e.g., a front end of an arm 113 that is supported by an ascending/descending instrument (not shown) such as a boat elevator. Accordingly, the wafer boat 105 and the cover part 109 are elevated in an integrated manner to be inserted into/separated from the processing chamber 101.

The film forming apparatus 100 includes a process gas supply mechanism 114 configured to supply process gases into the processing chamber 101 and an inert gas supply mechanism 115 configured to supply an inert gas into the processing chamber 101.

The process gas supply mechanism 114 includes a silicon precursor gas supply source 117a, an additive gas supply source 117b and an anneal gas supply source 117c.

In this embodiment, the silicon precursor gas supply source 117a supplies an SiH₄ gas as a silicon precursor gas into the processing chamber 101. The additive gas supply source 117b supplies an SnCl₄ gas as an additive gas into the processing chamber 101. The anneal gas supply source 117c supplies an N₂ gas or an H₂ gas as an anneal gas into the processing chamber 101.

The inert gas supply mechanism 115 includes an inert gas supply source 120. The inert gas supply source 120 supplies an N₂ gas as an inert gas into the processing chamber 101.

The silicon precursor gas supply source 117a is coupled to a dispersion nozzle 123a through a flow rate controller 121a and an on-off valve 122a. Likewise, the additive gas supply source 117b is coupled to a dispersion nozzle 123b (not shown) through a flow rate controller 121b and an on-off valve 122b. Similarly, the anneal gas supply source 117c is coupled to a dispersion nozzle 123c through a flow rate controller 121c and an on-off valve 122c. The dispersion nozzle 123b is not shown in FIG. 4.

Each of the dispersion nozzles 123a to 123c is formed of a quartz tube. Each nozzle pierces through the sidewall of the manifold 103 inward, bends upward, and extends vertically. At vertical portions of the dispersion nozzles 123a to 123c, a plurality of gas discharge holes 124a to 124c is formed spaced apart from each other by a predetermined distance, respectively. The silicon precursor gas, the additive gas and the anneal gas are approximately uniformly discharged from the respective gas discharge holes 124a to 124c into the processing chamber 101 in a horizontal direction.

The inert gas supply source 120 is coupled to a nozzle 128 through a flow rate controller 121d and an on-off valve 122d. The nozzle 128 penetrates through the sidewall of the manifold 103 and discharges the inert gas from a tip of the nozzle 128 into the processing chamber 101 in the horizontal direction.

At a portion opposite to the dispersion nozzles 123a to 123c in the processing chamber 101, an exhaust vent 129 is formed to exhaust the interior of the processing chamber 101. The exhaust vent 129 has an elongated shape formed by chipping the sidewall of the processing chamber 101 in the vertical direction. At a portion corresponding to the exhaust vent 129 of the processing chamber 101, an exhaust vent cover member 130 with a C-shaped section is installed by welding to cover the exhaust vent 129. The exhaust vent cover member 130 extends upward along the sidewall of the processing chamber 101, and defines a gas outlet 131 at the top of the processing chamber 101. An exhaust mechanism 132 including a vacuum pump is connected to the gas outlet 131. The exhaust mechanism 132 exhausts the interior of the processing chamber 101 to discharge the process gas used for the process and to change the internal pressure of the processing chamber 101 into a process pressure for the process.

A cylindrical body-shaped heating device 133 is installed around the outer periphery of the processing chamber 101. The heating device 133 activates a process gas supplied into the processing chamber 101, and heats a workpiece (e.g., the wafer 1 in this embodiment) loaded in the processing chamber 101.

For example, respective parts of the film forming apparatus 100 are controlled by a controller 150 including a microprocessor (computer). The controller 150 is connected to a user interface 151. The user interface 151 includes an input part including a touch panel and a keyboard for allowing an operator to input a command to control the film forming apparatus 100, and a display unit including a display for visually displaying an operation state of the film forming apparatus 100.

A memory part 152 is connected to the controller 150. The memory part 152 stores a control program for executing various processes in the film forming apparatus 100 under the control of the controller 150, and a program (i.e., a recipe) for causing the respective components of the film forming apparatus 100 to execute the respective processes in according to the process conditions. The recipe is stored in, e.g., a memory medium of the memory part 152. The memory medium may include a hard disk, a semiconductor memory, or a portable memory such as a CD-ROM, a DVD, a flash memory or the like. The recipe may be suitably transmitted from other device through, e.g., a dedicated line. If necessary, the recipe is read from the memory part 152 in response to a command received from the user interface 151. By executing a process according to the read recipe by the controller 150, the film forming apparatus 100 performs a desired process under the control of the controller 150.

In this example, Step S1 (of forming the additive-containing silicon film 4) and the subsequent Steps S2 and S3 (of crystallizing the silicon) described in the first embodiment are performed under the control of the controller 150. Steps S1 to S3 in the group IV semiconductor crystallizing method according to the first embodiment can be performed by the film forming apparatus 100 as shown in FIG. 4.

Step S4 of removing the segregated additive is performed by, e.g., an etching apparatus or a chemical mechanical polishing apparatus which is separated from the film forming apparatus 100.

However, if a supply source of an etching gas capable of etching the segregated additive is additionally installed in the film forming apparatus 100 and is configured to supply the etching gas into the processing chamber 101, all of Steps S1 to S4 in the group IV semiconductor crystallizing method according to the first embodiment can be performed by the film forming apparatus 100.

Although the present disclosure has been described according to the first and second embodiments and the modification, the present disclosure is not limited thereto. Other different embodiments and modifications may be made without departing from the spirit of the disclosure.

For example, although it has been illustrated that a film having the opening 2 formed on the process surface of the wafer 1 is the silicon oxide film 3, this film is not limited to the silicon oxide film but may be a silicon nitride film or other insulating film.

In addition, for example, although it has been illustrated in the second embodiment that the film forming apparatus 100 for performing the method of the present disclosure is a batch type film forming apparatus 100 for forming films on a plurality of wafers 1 at once, the film forming apparatus 100 is not limited to the batch type but may be a single-wafer film forming apparatus for forming films on a plurality of wafers 1 one by one.

In addition, the workpiece is not limited to the wafer 1 but the present disclosure may be applied to other substrates such as an LCD glass substrate and the like. Others, the present disclosure may be modified in different ways without departing from the spirit and scope of the disclosures.

According to the present disclosure in some embodiments, it is possible to provide a method for crystallizing a group IV semiconductor, which is capable of suppressing poly-crystallization of the group IV semiconductor and obtaining group IV semiconductor crystals closer to single crystals, and a film forming apparatus which is capable of performing the group IV semiconductor crystallizing method.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for crystallizing a group IV semiconductor to form group IV semiconductor crystals on a process surface of a workpiece on which a process is performed, the method comprising:
forming an additive-containing group IV semiconductor film on the process surface of the workpiece by supplying a group IV semiconductor precursor gas serving as a precursor of the group IV semiconductor and an additive gas which lowers a melting point of the group IV semiconductor and which includes an additive whose segregation coefficient is smaller than “1”;
liquefying the additive-containing group IV semiconductor film; and
solidifying the liquefied additive-containing group IV semiconductor film from the side of the process surface of the workpiece to form the group IV semiconductor crystals.

2. The method of claim 1, wherein the process surface includes the same crystals of the group IV semiconductor as the group IV semiconductor included in the group IV semiconductor precursor gas.

3. The method of claim 1, wherein liquefying the additive-containing group IV semiconductor film includes applying heat equal to the melting point of the additive-containing group IV semiconductor film or more and less than a melting point of the workpiece, to the additive-containing group IV semiconductor film.

4. The method of claim 1, wherein solidifying the liquefied additive-containing group IV semiconductor film includes dissipating heat from the liquefied additive-containing group IV semiconductor film through the workpiece.

5. The method of claim 1, wherein the additive-containing group IV semiconductor film formed on the process surface in forming an additive-containing group IV semiconductor film is amorphous.

6. The method of claim 1, wherein a film having an opening through which the process surface is exposed is formed on the process surface, and
wherein the additive-containing group IV semiconductor film is formed at least inside the opening.

7. The method of claim 6, wherein an insulating film is exposed to a side wall of the opening.

8. The method of claim 7, wherein the insulating film is amorphous.

9. The method of claim 1, wherein the additive is metal.

10. The method of claim 1, wherein the additive lowers the melting point of the additive-containing group IV semiconductor until the additive-containing group IV semiconductor can be liquefied at a temperature zone ranging from 500 degrees C. or more to 900 degrees C. or less.

11. The method of claim 1, wherein the group IV semiconductor is one selected from a group consisting of silicon and germanium.

12. The method of claim 1, wherein the additive is tin.

13. The method of claim 1, further comprising: after solidifying the liquefied additive-containing group IV semiconductor film, removing the additive, which is segregated in a side opposite to the process surface, from the solidified additive-containing group IV semiconductor film.

14. A film forming apparatus for forming a film of a group IV semiconductor on a process surface a workpiece on which a process is performed, the apparatus comprising:
a processing chamber in which the workpiece is subjected to a predetermined process;
a gas supply mechanism including a group IV semiconductor precursor gas supply source for supplying a group IV semiconductor precursor gas serving as a precursor of the group IV semiconductor into the processing chamber and an additive gas supply source for supplying an additive gas which lowers a melting point of the group IV semiconductor and which includes an additive whose segregation coefficient is smaller than “1”;
a heating device for heating an interior of the processing chamber; and
a controller for controlling the gas supply mechanism and the heating device,
wherein the controller controls the gas supply mechanism and the heating device to perform the group IV semiconductor crystallizing method of claim 1.

15. The film forming apparatus of claim 14, wherein the gas supply mechanism further includes an etching gas supply source for supplying a gas, which is capable of etching a segregated additive, into the processing chamber, and
wherein the controller controls the gas supply mechanism and the heating device to perform the group IV semiconductor crystallizing method of claim 13.
